(19) United States
(12) Patent Application Publication
(10) Pub. No.: US 2006/0215456 A1
(43) Pub. Date: Sep. 28, 2006

(54) Disk array data protective system and method

(75) Inventor: Chih-Wei Chen, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/088,312

(22) Filed: Mar. 23, 2005

(51) Int. Cl. G11C 11/34

(52) U.S. Cl. 365/185.22

(57) ABSTRACT

A disk array data protective system and method is provided to ensure a computer host easily backs up data stored in a disk of a disk array about to be damaged. The disk array data protective system monitors the operations of each disk of a disk array and predicts oncoming damage according to disk performance parameters. The system also records the status of use of each disk in an array. Thus, when oncoming damage to a disk is detected, the system copies the stored data to a backup disk and updates the recorded status of use of the disks in order to redistribute the status of use of the disks, such that a new disk array is established. As result of the present invention, both the efficiency of data access and the reliability of data storage of the disk array are enhanced.

### FIELD OF THE INVENTION

The present invention relates to a disk array data protective system and method, and more particularly, to a disk array data protective system and method using Self-Monitoring Analysis and Reporting Technology (S.M.A.R.T.) for protecting the data stored in a disk array.

### BACKGROUND OF THE INVENTION

Due to their relatively large capacity and efficient accessing speed, disks are currently the most popular data storage device. However, although there has been great enhancement in the capacity, efficiency and reliability of the disks in recent years, they still do not satisfy the demands of high performance processors. Therefore, the disks remain a bottleneck to the development of computer systems. In order for the disk to satisfy the requirement of high efficiency of data access, many different solutions have been disclosed. A scheme called “Redundant Array of Inexpensive Disks” (RAID) introduced by a research team at the University of Berkeley in California, U.S. provides one of such solutions.

RAID assembles ordinary disks into a disk array. When a computer host writes data the disk array, a RAID controller divides the data to be written into multiple data blocks, then each data block is concurrently written to the disk array. While the computer host reads data from the disk array, the RAID controller concurrently reads the data from each disk of the disk array, which is then reassembled for the computer host. Concurrent reading and writing operations enhance the efficiency of data accessing. Moreover, RAID also uses techniques such as mirroring, parity checks, and the like, to enhance the ability of system fault tolerance and assure reliability of the data.

Being a high performance storage system, RAID has been used extensively. Today, several levels of RAID have been developed including RAID0, RAID1, RAID2, RAID3, RAID4, RAID5, etc.

However, there are disadvantages to the foregoing RAID levels. RAID0 performs disk stripping, that is data are divided for storage, thus normally at least two disks are required to assemble a disk array to implement the storage. In a subsystem of the disk array, multiple disks are processed in parallel. During data accessing, these disks are separately and concurrently read or written. For a data writing process, the data required to be stored is written into multiple disks in unit of “sector” as prescribed by the system. As shown in FIG. 1, data to be stored 1 is split into four sectors: data sectors 10, 11, 12 and 13. Through a disk array that consists of a first disk 20, a second disk 21, a third disk 22 and a forth disk 23, each data sector is separately written into the different disks, for example, the data sector 10 is written into the first disk 20, the data sector 11 is written into the first disk 21, the data sector 12 is written into the first disk 22, and the data sector 13 is written into the first disk 23 etc. Data is written into different disks of the disk array in a sector-by-sector manner.

The main disadvantage of RAID0 is its low fault-tolerance, which results in low data security. Because it splits data into sectors and stores them on different disks, when any disk of the disk array is damaged (e.g., the third disk 22), the whole disk array is affected, which means if any data on a disk is damaged, the whole data cannot be read correctly. The severity of this disadvantage increases with an accompanying increase in total number of disks provided by the disk array.

RAID1 was developed because of the foregoing disadvantage of low fault-tolerance of RAID0. In RAID1, also called a disk mirror, every disk has a corresponding “mirror” (disk). Any data written to a disk is also copied to its corresponding mirror. The system can read the data from any one disk in the mirrored pair. Since mirroring disks are required to be installed, the actual usable storage capacity is only half of the total disk capacity of the RAID1. RAID1 thus solves the problem of the low data security of RAID0 by increasing the cost of the system.

Another level of disk array, RAID5, which divides and writes data into multiple disks in parallel, further utilizes an error-correcting code to implement a series of operations to restore the original data when error occurs. However, if a severe fault occurs in RAID5, the operation of the error correcting code is overly time consuming. Hence it does not meet the requirement of high accessing efficiency. Therefore, in order to achieve the objectives of time efficiency and effective use of storage capacity, RAID0 is still the most popular disk array in use.

For that reason, how to provide a disk array data protective system to overcome the foregoing technical problems, and to enhance both efficiency of data access and reliability of data storage of the disk array are the main problems to be solved.

### SUMMARY OF THE INVENTION

In order to resolve problems in the prior art, a main objective of the present invention is to provide a disk array data protective system and method, which enhances the reliability of data storage of a disk array.

Another objective of the invention is to provide a disk array data protective system and method, which results in a high efficiency of data access.

In accordance with the above and other objectives, the invention provides a disk array data protective system and method.

The disk array data protective system of the present invention ensures a computer host successfully accesses the data stored on a disk of a disk array before the disk is damaged. The disk array data protective system comprises a backup disk, a disk status-monitoring module that monitors operations of each disk in the disk array and detects any oncoming damage to the disks according to disk performance parameters, a disk usage recording module that records status of use of each disk in the disk array, and a damage management module that copies data in one of the disks detected to be damaged by the disk status-monitoring module to the backup disk and then updates status of disk use recorded by the disk usage recoding module in order to redistribute the status of disk use and establishes a new disk array.

The disk array data protective method is used in the disk array data protective system described above. The disk array data protective method comprising the following steps of: the disk array data protective system monitoring the operations of each disk in the disk array and detecting oncoming damage to a disk of the disk array according to disk performance parameters; the disk array data protective system recording the status of use of each disk of the disk array; and the disk array data protective system copying the data stored in the disk detected to have an oncoming damage into one of the backup disks and updating the status of disk use in order to redistribute the status of disk use and establish a new disk array.

Compared to the aforementioned conventional disk array data protective technology, the disk array data protective system and method of the present invention not only enhances efficiency of data access but also ensures reliability of data storage in a disk array, thereby successfully implements operations of data storage.

### BRIEF DESCRIPTION OF THE DRAWINGS

FIG. 1 is a schematic block diagram showing data storage of a disk array of the prior art;

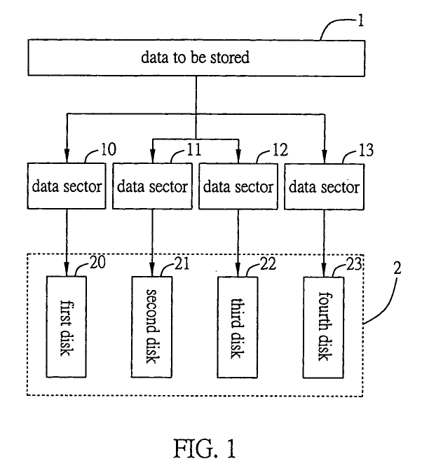

FIG. 2 is a schematic block diagram showing the basic structure of a disk array data protective system of the present invention;

FIG. 3 is a flow chart showing the basic operation of disk damage management of a disk array data protective system of the present invention; and

FIG. 4 is a schematic block diagram of a new disk array established after a hypothetically damaged disk is eliminated using the disk array data protective system and method of the present invention.

### DETAILED DESCRIPTION OF THE PREFERRED EMBODIMENTS

Reference will now be made in detail to the preferred embodiment of the present invention, the advantages and functions of the present invention can be understood by those skilled in the art after reading the detailed description. The present invention should cover various modifications and variations made to the herein-described structure and operations of the present invention, provided they fall within the scope of the present invention.

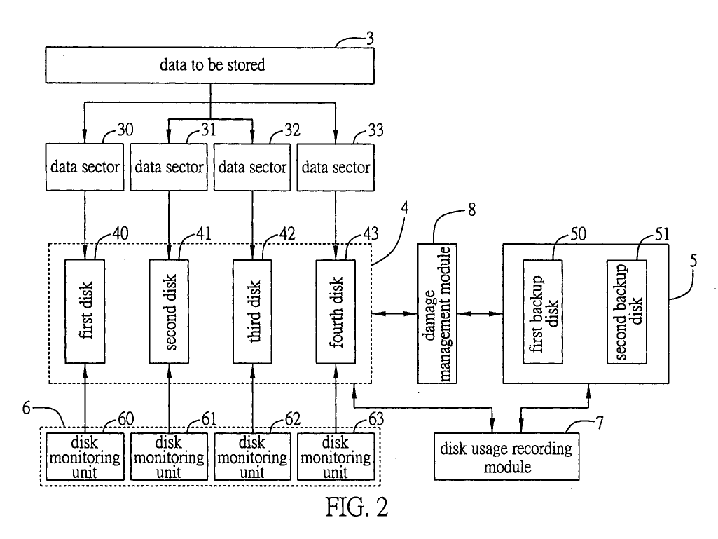

FIG. 2 is a block diagram showing the basic structures of the disk array data protective system of the present invention. The present invention ensures data security of a disk array and prevents data loss due to damage of a disk while a computer host (not shown) accesses the disk array.

As shown in the diagram, the disk array data protective system splits data to be stored 3 into multiple data blocks, i.e. data sector 30, data sector 31, data sector 32 and data sector 33. Furthermore, the disks used in the present invention are divided into two groups, one is a disk array 4 for data storage and the other is a backup disk module 5 for storing data which is stored on a possibly damaged disk in the disk array 4. Disk array 4 comprises a first disk 40, a second disk 41, a third disk 42 and a forth disk 43. The disk array 4 is preferably a RAID 0, and the configurations of disk array 4 are the first disk 40, the second disk 41, the third disk 42, and the forth disk 43. Out of those, each disk stores in parallel the contents of a corresponding data sector. The backup disk module 5 comprises a first backup disk 50 and a second backup disk 51, which can be unrestrainedly modified or expanded in accordance with different needs of users during practical operations. The backup disk in general is a blank disk without any stored contents.

A disk status-monitoring module 6 is provided to monitor the operations of each disk of the disk array 4 by monitoring disk performance parameters to detect any oncoming disk damage. The performance parameters comprises at least one of a rotating velocity of a disk read/write head and a quantity of the bad sectors in a disk of the disk array 4. In this preferred embodiment, disk status-monitoring module 6 comprises a disk monitoring unit 60, a disk monitoring unit 61, a disk monitoring unit 62 and a disk monitoring unit 63. The disk monitoring units of the disk status-monitoring module 6 utilizes a Self-Monitoring Analysis and Reporting Technology (S.M.A.R.T.) developed by Seagate Technology, Inc., which implements self-monitoring of each disk (60, 61, 62, and 63) of the disk array 4 in order to detect problems and inform users in advance, therefore allowing users to make a copy immediately or carry out actions to rescue data. Since the S.M.A.R.T is a well-known technology, details are not discussed further.

A disk usage recording module 7 is used to record status of use of each disk of the disk array 4 and establish corresponding configuration file in accordance with the operating status of the disk array 4. In the preferred embodiment, a computer host will then be able to determine the current status of the disk array via the configuration file recorded in the disk usage recording module 7 during data access of the disk array 4.

After detection of possible disk damage based on the performance parameters by the disk status-monitoring module 6, the damage management module 8 redistributes the status of use of each disk in the disk array and updates the contents recorded in the disk usage recording module 7 (including for example the status of use of each disk of the disk array 4 and the established configuration file corresponding to the operating status of the disk array 4).

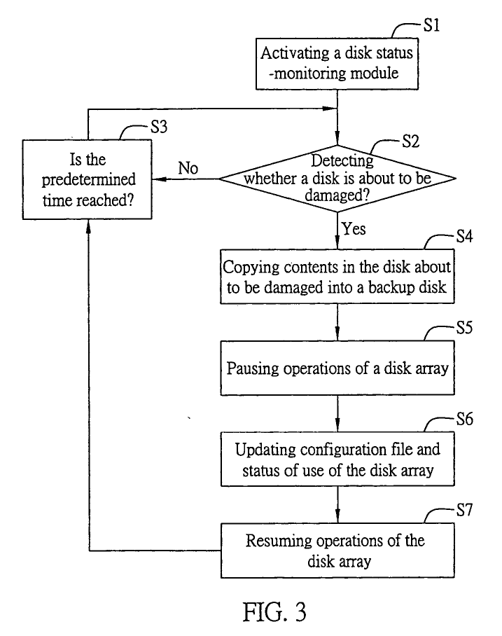

FIG. 3 is a flow chart showing the fundamental steps carried out by the disk array data protective system of the present invention in case of a faulty (damaged) disk.

At step S1, the disk status-monitoring module 6 is activated, which enables the disk monitoring units 60-63 to regularly monitor the first disk 40, the second disk 41, the third disk 42 and the forth disk 43 of disk array 4 respectively. In the preferred embodiment, the Self-Monitoring Analysis and Reporting Technology (S.M.A.R.T.) is used to achieve the above monitoring. Then, step S2 is proceeded.

At step S2, the disk status-monitoring module 6 monitors any oncoming damage of each disk of the disk array 4 according to disk performance parameters comprised of the rotation velocity of the disk read/write head and the quantity of the bad sectors. If the performance parameter of disk array 4 is within the normal limit, the system proceeds to step S3, otherwise, it proceeds to step S4.

At step S3, the disk status-monitoring module 6 is subject to a set time counter, so that when time counting reaches the set time, the system proceeds to step S2 for continual monitoring of the operation of each disk of disk array 4. The set time for the preferred embodiment can be pre-set by users, for instance, the first disk 40, the second disk 41, the third disk 42 and the forth disk 43 of the disk array 4 can be monitored by the disk status-monitoring module 6 every ten minutes as pre-set by the user.

At step S4, when disk status-monitoring module 6 detects oncoming damage of one of the disks of disk array 4, a damage message is sent to the damage management module 8 to implement damage management, by which the contents in the storage data sectors of the disk detected with oncoming damage is copied to the first backup disk 50 of the backup disk module 5, ensuring data stored on the about-to-be-damaged disk is not lost. In this preferred embodiment, the disk about to be damaged in the near future is assumed to be the third disk 42 of the disk array 4; the system then proceeds to S5.

At step S5, the damage management module 8 pauses the operation of the disk array 4; the system then proceeds to step S6.

At step S6, the disk usage recording 7 updates configuration file of the disk array 4 and the status of use of each disk in the disk array 4. In this preferred embodiment, parameters of the third disk 42 in the original configuration file is removed and subsequently replaced by the parameters of the first backup disk 50 of the backup disk module 5 in a new configuration file for a disk array 4′, so that the new configuration file has the parameters of the first disk 40, the second disk 41, the first backup disk 50 and the forth disk 43. The disk usage recording module 7 also updates the status of use of each disk in the disk array 4′, where the status indicates that the disks used for the disk array 4′ are the first disk 40, the second disk 41, the first backup disk 50 and the forth disk 43, the backup disk module 5 now comprises only the second backup disk 51, and the third disk 42 is a disk about to be damaged; the system then proceeds to step S7.

At step S7, the damage management module 8 resumes the operations of the disk array 4′ based on the new configuration file stored in the disk usage recording module 7, and then the system returns to step S3 to repeatedly implements steps S2 to S7.

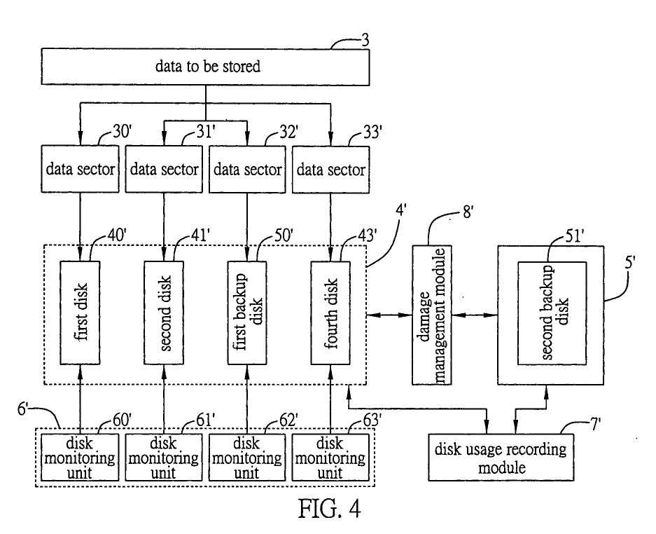

FIG. 4 is a schematic block diagram which shows operating status of the new disk array 4′ after eliminating the disk possibly to be damaged by using the disk array data protective system and method of the present invention. As shown, the new disk array 4′ comprises: the first disk 40′, the second disk 41′, the first backup disk 50′ and the forth disk 43′. Out of these, contents of the first backup disk 50′ are the copies of data stored in the third disk 42 (shown in FIG. 2) detected to have an oncoming damage, therefore, the integrity of data to be stored 3′ is not affected and the security of disk array during data storing is assured.

Therefore, the disk array data protective system and method of the present invention not only enhances efficiency of data access but also ensures reliability of data storage of a disk array, which overcomes the technical problems in the conventional technology and successfully implements operations of data storage.

The invention has been described using exemplary preferred embodiments. However, it is to be understood that the scope of the invention is not limited to the disclosed embodiments. For instance, in step S2 shown in FIG. 3, when a disk status-monitoring module 6 detects that disk performance parameters of each disk of the disk array 4 fall within normal limits, the system then proceeds to S3. The disk status-monitoring module 6 can also not implement the set time counting as shown in step S3, therefore, the disk status-monitoring module 6 will continually perform step S2 until detection of oncoming damage to one of the disks of the disk array 4, then the disk array data protective system implements steps S2 to S7. Thus, the present invention is intended to cover various modifications and similar arrangements. The scope of the claims, therefore, should be accorded the broadest interpretation so as to encompass all such modifications and similar arrangements.

What is claimed is:

1. A disk array data protective system ensuring a computer host successfully accesses data stored in a disk of a disk array before the disk is damaged, the disk array data protective system comprising:
a backup disk;
a disk status-monitoring module that monitors operations of each disk in the disk array and detects any oncoming damage to the disks according to disk performance parameters;
a disk usage recording module that records status of use of each disk in the disk array; and
a damage management module that copies data in one of the disks detected to be damaged by the disk status-monitoring module to the backup disk and then updates status of disk use recorded by the disk usage recoding module in order to redistribute the status of disk use and establishes a new disk array.

2. The disk array data protective system of claim 1, wherein a Self-Monitoring Analysis and Reporting Technology (S.M.A.R.T) is applied in the disk status-monitoring module to achieve the monitoring of the operations of each disk in the disk array.

3. The disk array data protective system of claim 1, wherein the disk array employs a RAID level 0 to carry out data storage.

4. The disk array data protective system of claim 1, wherein oncoming damage to a disk is detected by the disk status-monitoring module according to the disk performance parameters comprising at least one of rotation velocity of a read/write head and quantity of bad sectors in the disks.

5. The disk array data protective system of claim 1, wherein the damage management module further establishes a corresponding configuration file based on the redistributed status of disk use, thus allowing the computer host to resume operations of the disk array according to the newly established configuration file.

6. A disk array data protective method is used in a disk array data protective system with backup disks, ensuring a computer host successfully accesses the data stored in a disk before the disk is damaged, the disk array data protective method comprising:
a disk array data protective system monitoring the operations of each disk in the disk array and detecting oncoming damage to a disk of the disk array according to disk performance parameters;
a disk array data protective system recording the status of use of each disk of the disk array; and
a disk array data protective system copying the data stored in the disk detected to have an oncoming damage into one of the backup disks and updating the status of disk use in order to redistribute the status of disk use and establish a new disk array.

7. The disk array data protective method of claim 6, wherein the step of monitoring the operations of each disk of the disk array is by a Self-Monitoring Analysis and Reporting Technology (S.M.A.R.T.).

8. The disk array data protective method of claim 6, wherein the disk array employs a RAID level 0 to carry out data storage.

9. The disk array data protective method of claim 6, wherein the oncoming damage to a disk is detected by the disk array data protective system according to the disk performance parameters comprising at least one of rotation velocity of a read/write head and quantity of bad sectors in the disks.

10. The disk array data protective method of claim 6, wherein after the step of redistributing the status of disk use, further establishing a corresponding configuration file based on the redistributed status of disk use, thus allowing the computer host to resume operations of the disk array according to the newly established configuration file.
